(19) United States
(12) Patent Application Publication
(10) Pub. No.: US 2010/0055826 A1
(43) Pub. Date: Mar. 4, 2010

(54) Methods of Fabrication of Solar Cells Using High Power Pulsed Magnetron Sputtering

(75) Inventors: Dalong Zhong, Niskayuna, NY (US); James Neil Johnson, Scotia, NY (US); Xiaolan Zhang, Niskayuna, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/198,732

(22) Filed: Aug. 26, 2008

(51) Int. Cl. H01L 21/00

(52) U.S. Cl. 438/84; 257/E21.001

(57) ABSTRACT

A method of fabricating a solar cell is provided. The method includes depositing a transparent conductive contact layer on a surface of a substrate, where the transparent conductive contact layer is configured to act as a front electrode for the solar cell, depositing a window layer over the transparent conductive contact layer, depositing an absorber layer on the window layer, wherein the absorber layer and the window layer are oppositely doped and form a semiconductor junction, and where at least one of the window layer or the absorber layer is deposited by employing high power pulsed magnetron sputtering, and depositing an electrically conductive film on the semiconductor junction, wherein the electrically conductive film is configured to act as a back electrode layer for the solar cell.

### BACKGROUND

The invention relates generally to the field of solar cells, and more particularly to methods of fabrication of solar cells.

Solar cells are used for converting solar energy into electrical energy. Typically, in its basic form, a solar cell includes a semiconductor junction made of two or three layers that are disposed on a substrate layer, and two contacts (electrically conductive layers) for passing electrical energy in the form of electrical current to an external circuit.

Thin-film solar cells have a great potential for cost reduction because they require only a small amount of materials deposited directly on large area substrates, and their manufacture is suited to fully integrated processing and high throughputs. Alternatives for substrate materials that can be employed in solar cells include glass, titanium, steel, or polyimide. The drawback of metal foils (e.g., titanium and steel) is that they are electrically conductive, and thus, an electrically isolating layer is needed in order to allow monolithic series-interconnection of the cells. Such an isolation layer is not easy to make without local defects that may cause shunting of the solar cells. Further, the polyimide films commercially available deteriorate at temperatures above 400° C. For example, polyimides have high thermal expansion at such high temperatures. Because subsequent processing may involve temperatures above 400° C., these polyimides may not be useful in accordance with prior fabrication techniques. The fabrication method for low-cost flexible modules on alternative substrates have to be developed and improved to take full advantage of roll-to-roll production and monolithic interconnection.

In conventional methods, different layers of the solar cell are deposited using different fabrication techniques depending on the material employed in these different layers. For example, the deposition techniques employed for semiconductor layers are chosen based on whether single crystalline materials, polycrystalline materials, or amorphous materials are employed. Single crystalline materials may be deposited using deposition techniques, such as molecular beam epitaxy (MBE). However, most of the deposition techniques require high temperatures (greater than about 400° C.), and such high temperatures are not suitable for flexible substrates, such as polyimide substrates. Further, solar cells made using deposition techniques known in the art may require post-processing treatments, such as annealing at temperatures greater than 400° C., to improve the cell efficiency. Such treatments reduce the efficiency of the fabrication process and also result in additional fabrication cost. Further, high temperatures may deteriorate the material of some layers in a solar cell. For example, the bottom cell has to survive the subsequent processing of the top cell for tandem cells. In the case of solar cells employing copper gallium indium diselenide (CIGS) or cadmium telluride, there is at least one high temperature (e.g., greater than 500° C.) step either during deposition or post-deposition treatment for high efficiency cells.

Accordingly, it is desirable to develop fabrication techniques that allow for fabrication with flexible substrates, such as flexible polymer web, and enable low temperature processing.

### BRIEF DESCRIPTION

In accordance with an aspect of the present technique, a method of fabricating a thin-film solar cell is provided. The method includes depositing a transparent conductive contact layer on a surface of a substrate, where the transparent conductive contact layer is configured to act as a front electrode for the solar cell, depositing a window layer over the transparent conductive contact layer, depositing an absorber layer on the window layer, where the absorber layer and the window layer are oppositely doped and form a semiconductor junction, and where at least one of the window layer or the absorber layer is deposited by employing high power pulsed magnetron sputtering, and depositing an electrically conductive film on the semiconductor junction, where the electrically conductive film is configured to act as a back electrode layer for the solar cell.

In accordance with one aspect of the present technique, a method of fabricating a thin-film solar cell is provided. The method includes depositing a transparent conductive contact layer on a surface of a substrate, depositing an n-type cadmium sulphide window layer on the transparent conductive contact layer, depositing a p-type cadmium telluride absorber layer on the window layer, depositing an electrically conductive film as a back electrode layer, and where at least one of the layers is deposited by employing high power pulsed magnetron sputtering.

In accordance with yet another aspect of the present technique, a method of fabricating a solar cell is provided. The method includes depositing an electrically conductive layer on a surface of a substrate, depositing an absorber layer on the electrically conductive layer, depositing a window layer on the absorber layer, where the absorber layer and the window layer are oppositely doped and form a semiconductor junction, and where high power pulsed magnetron sputtering is employed to deposit at least one of the absorber layer and the window layer; and depositing a transparent conductive contact layer on the window layer.

In accordance with another aspect of the present technique, a method of fabricating a solar cell is provided. The method includes depositing a conductive layer on a first surface of a substrate, depositing a p-type CIGS absorber layer on the conductive layer, depositing an n-type window layer on the absorber layer, depositing a transparent conductive contact layer, where at least one of the layers is deposited by employing high power pulsed magnetron sputtering.

### DRAWINGS

These and other features, aspects, and advantages of the present invention will become better understood when the following detailed description is read with reference to the accompanying drawings in which like characters represent like parts throughout the drawings, wherein:

FIG. 1 illustrates a flow chart for a method of fabricating a solar cell by employing high power pulsed magnetron sputtering;

FIG. 2 is a cross-sectional view of a solar cell fabricated using the method of FIG. 1;

FIG. 3 illustrates a flow chart for a method of fabricating a solar cell having a superstrate configuration by employing high power pulsed magnetron sputtering;

FIG. 4 is a cross-sectional view of a solar cell fabricated using the method of FIG. 3; and

FIG. 5 is a schematic representation of a roll-to-roll process for fabricating a solar cell by employing high power pulsed magnetron sputtering.

### DETAILED DESCRIPTION

Embodiments of the present technique provide methods of fabricating diode structures, such as solar cells. The methods employ high power pulsed magnetron sputtering to deposit different layers of the solar cells. As will be described in detail below, in some embodiments, all or some of the layers of the solar cells may be deposited using the high power pulsed magnetron sputtering.

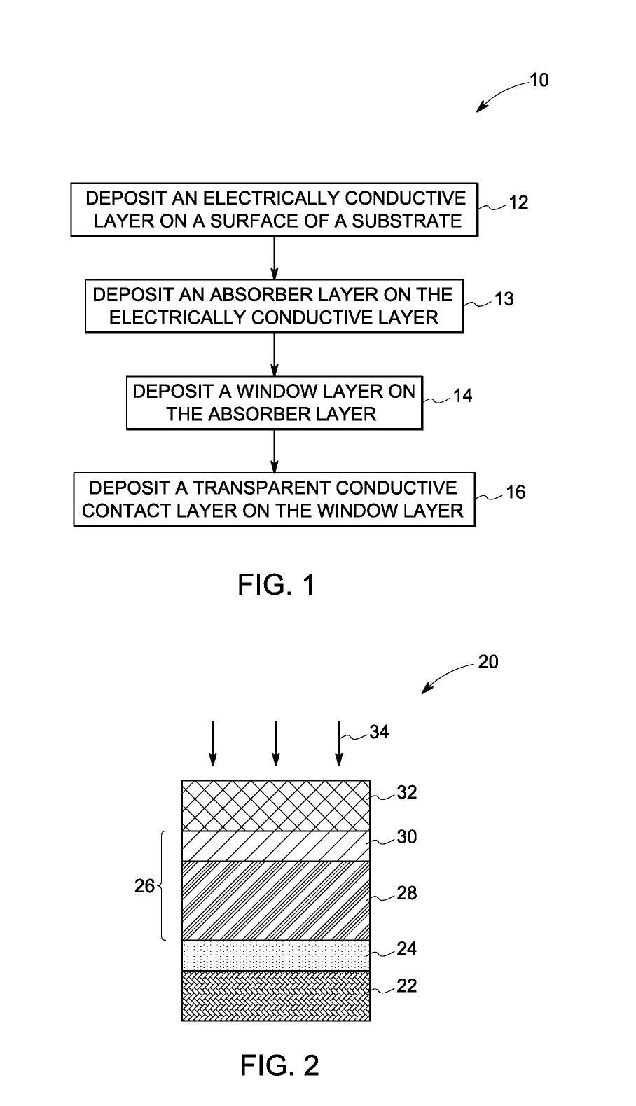

As illustrated in FIG. 1, a flow chart 10 illustrates a method of fabricating a solar cell. The method includes depositing an electrically conductive layer on a surface of a substrate (block 12). The electrically conductive layer provides ohmic contact to the solar cell. Although not illustrated, the electrically conductive layer may contain one or more layers. For example, the electrically conductive layer may contain a dual layer structure, where one layer provides stable contact with the semiconductor junction, and the other layer provides electrical conductivity. At block 13, an absorber layer is deposited on the electrically conductive layer. Next, a window layer is deposited on the absorber layer (block 14). The absorber layer and the window layer are oppositely doped to form a semiconductor junction. For example, depositing the semiconductor junction may include depositing a p-type absorber layer on the electrically conductive layer, and depositing an n-type window layer on the absorber layer. At least one of the absorber layer and the window layer may be deposited by employing high power pulsed magnetron sputtering. In one embodiment, the semiconductor junction may include an intrinsic layer to form a p-i-n junction. At block 16, a transparent conductive contact layer is deposited on the window by employing high power pulsed magnetron sputtering. The transparent conductive contact layer may form either a single or multi-layer ohmic contact. In one embodiment, a high resistance transparent oxide layer may be deposited on the window layer prior to depositing the transparent conductive contact layer. In one embodiment, the high resistance transparent oxide layer may be deposited by employing high power pulsed magnetron sputtering. The high resistance transparent oxide layer may include zinc oxide (ZnO), tin oxide (SnOₓ), zinc tin oxide (Zn₂SnO₄), zinc magnesium oxide (ZnMgO₂), titanium dioxide (TiO₂), zirconium dioxide (ZrO₂), or other transition metal oxides.

In one embodiment, the electrically conductive layer, the transparent conductive contact layer, and one or both of the absorber layer and the window layer may be deposited using high power pulsed magnetron sputtering. In the embodiment where only one of the absorber layer and the window layer is deposited using the high power pulsed magnetron sputtering, the other layer may be deposited using any other suitable deposition technique other than high power pulsed magnetron sputtering. In another embodiment, the conductive layer, the transparent conductive contact layer may be deposited using deposition techniques, such as but not limited to, spin coating, spray coating, chemical vapor deposition, physical vapor deposition, or the like. In this embodiment, either both the absorber layer and the window layer may be deposited using the high power pulsed magnetron sputtering, or one of the absorber layer and the window layer may be deposited using the high power pulsed magnetron sputtering and the other layer may be deposited using a suitable deposition technique other than the high power pulsed magnetron sputtering.

As will be appreciated, high power pulsed magnetron sputtering facilitates production of a highly ionized flux of target material to the substrate, thereby facilitating depositing improved thin-film layers with high material utilization, high deposition rate while maintaining low substrate temperatures. Conventional magnetron sputtering applies a power density to the target not greater than 10-20 W/cm². In certain embodiments, the high power pulsed magnetron sputtering includes a power density in a range of about 0.10 kW/cm² to about 1 kW/cm², and a current density in a range of about 0.2 A/cm² to about 2 A/cm². In one embodiment, the high power pulsed magnetron sputtering includes a pulse length in a range of about 0.2 milliseconds to about 3 milliseconds. In another embodiment, the high power pulsed magnetron sputtering includes a pulse length in a range of about 0.5 milliseconds to about 1.5 milliseconds. In one embodiment, the high power pulsed magnetron sputtering results in a modulated pulse plasma in a frequency range of about 1 Hz to about 1000 Hz. In one embodiment, the ratio of ionic species to neutral species in plasma is greater than about 30 percent.

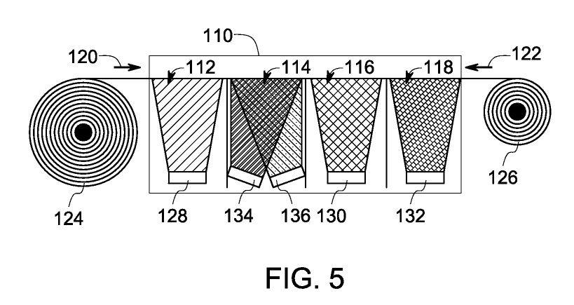

Further, as will be discussed in detail with respect to FIG. 5, in certain embodiments, the high power pulsed magnetron sputtering system includes a modular set-up having two or more modules. In one embodiment, the high power pulsed magnetron sputtering system includes separate modules for depositing the different layers of the solar cell, such as the ohmic contact, the absorber layer, the window layer, and the transparent conductive contact layer.

In certain embodiments, the substrate temperature (in K) during the deposition of the various layers such as the layers of the junction, the electrically conductive layer, and the transparent conductive contact layer may be lower than 0.3 times the melting point (Tₘ, in K) of a material being deposited. In some embodiments, the substrate temperature may be less than or equal to 0.2 Tₘ. Since the plasma is highly ionized, growing multicrystalline films, controlling their phase composition and modifying the film microstructure may be accomplished at reduced substrate temperature using high power pulsed magnetron sputtering. Due to the temperature limitations, the as-deposited absorber layer and the window layer may be polycrystalline. In one embodiment, the as-deposited layers are highly dense, smooth and conformal. As used herein, the term “as-deposited layers” refers to layers that are not post treated (such as annealing at a high temperature and controlled atmosphere) following the deposition of the layers to fabricate the solar cell. In fact, in certain embodiments, the methods of fabricating the solar cell do not include a post-deposition step, such as annealing at a high temperature and controlled atmosphere. By avoiding the post-deposition step(s), the fabrication method may be made more efficient and less time consuming. In certain embodiments, the as-deposited layers are substantially polycrystalline, and the grain size is equal or greater than that of the same layer deposited by conventional sputtering at substrate temperature higher than 0.5 Tₘ, while substantially decreasing the amount of defects, such as voids or pin-holes in the as-deposited layers.

In some embodiments, a grain size of the different layers of the solar cell is greater than about 50 nm. In other embodiments, the grain size of the layers is in a range from about 100 nm to about 2000 nm, depending on the layer thickness. Further, compared to conventional sputtering and evaporation, the high power pulsed magnetron sputtering may facilitate lower defect density in the as-deposited layers even at lower substrate temperature. For example, a non-dopant defect density of the as-deposited layers is in a range of about 10¹⁴ to about 10¹⁵ cm⁻³, or less. In one embodiment, the as-deposited layers may be substantially free of one or more of Kirkendall voids, voids between grains in polycrystals, and voids within grains at twin terminations and dislocations.

FIG. 2 illustrates a solar cell 20 fabricated by employing the method of FIG. 1. The solar cell 20 includes a substrate 22. In one embodiment, the substrate 22 is a flexible substrate. In one embodiment, the substrate 22 may be transparent, translucent or opaque. Non-limiting examples of the substrate may include glass, metal, high temperature polyimide, low temperature polyimide, or highly transparent polymers, such as polyethylene napthalate (PEN), polyethylene terephthalate (PET), polycarbonate, or combinations thereof. The substrate 22 or the solar cell 20 may have a width in a range from about 0.5 m to about 2 m. In embodiments where there is another solar cell below the substrate 22, the electrically conductive layer 24 disposed on the substrate 22 may be optically transparent to visible light to enable passing of light from the conductive layer 24 onto other solar cell. In other embodiments, the electrically conductive layer 24 may or may not be transparent. In these embodiments, the conductive layer 24 may be made of materials, such as but not limited to molybdenum or doped zinc telluride (ZnTe), which are non-transparent.

The semiconductor junction 26 disposed on the conductive layer 24 includes an absorber layer 28 and a window layer 30 that are oppositely doped. In one embodiment, the absorber layer 28 includes a p-type semiconductor material and the window layer 30 includes an n-type semiconductor material to form a p-n junction. In this embodiment, the absorber layer 28 comprises copper indium disulfide (CIS), copper indium diselenide (CIS), copper indium gallium diselenide (CIGS), copper indium gallium sulfur selenium (CIGSS), copper indium gallium aluminum sulfur selenium (Cu(In,Ga,Al)(S,Se)₂), copper zinc tin sulfide (CZTS) and other CIS-based systems; amorphous silicon, hydrogenated amorphous silicon, microcrystalline silicon, nanocrystalline silicon, or other silicon-based systems; cadmium telluride (CdTe), cadmium zinc telluride (CdZnTe), cadmium magnesium telluride (CdMgTe), mercury cadmium telluride (HgCdTe), or other CdTe-based systems; or combinations thereof. The minimum thickness of the absorber layer 28 may be influenced by the depletion width and absorption coefficient of the material. In one embodiment, a thickness of the absorber layer is in a range of about 200 nanometers to about 5 microns. Although not illustrated, in some embodiments, the semiconductor junction may be a p-i-n junction. The intrinsic layer may include other materials, such as zinc telluride and zinc selenide.

A transparent conductive contact layer 32 is disposed on the semiconductor junction 26. In one embodiment, the transparent conductive contact layer may include an oxide material. For example, the contact layer may include cadmium tin oxide (Cd₂SnO₄), tin oxide or zinc oxide. Advantageously, Cd₂SnO₄ exhibits high electrical conductivity, high optical transmission. In addition, Cd₂SnO₄ has a smooth surface morphology, and good chemical and environmental stability which make it a desirable candidate for a contact layer. In one embodiment, an electrical conductivity of the oxide contact layer may be increased by doping the contact layer. For example, zinc oxide may be doped with one or more of aluminum, gallium, indium, or boron. Non-limiting examples of dopants may include aluminum, gallium, boron, fluorine, indium, niobium, antimony, or combinations thereof. The light enters the solar cell through the transparent conductive contact layer 32 as illustrated by arrow 34.

In one embodiment, the window layer 30 of the solar cell 20 is made of n-type material and the absorber layer 28 is made of p-type CIGS. In this embodiment, the thickness of the window layer 30 is in a range from about 20 nm to about 200 nm, and the thickness of the absorber layer 28 is in a range from about 1000 nm to about 2500 nm. Further, the transparent conductive includes zinc oxide doped with aluminum, and the electrically conductive layer comprises molybdenum. The substrate 22 may include a glass, a metal or a polymer. Although not illustrated, in one embodiment a high resistance transparent oxide layer may be present between the window layer 30 and the transparent conductive contact layer 32. The high resistance transparent oxide layer may include zinc oxide (ZnO), tin oxide (SnOₓ), zinc tin oxide (Zn₂SnO₄), zinc magnesium oxide (ZnMgO₂), titanium dioxide (TiO₂), zirconium dioxide (ZrO₂), or other transition metal oxides.

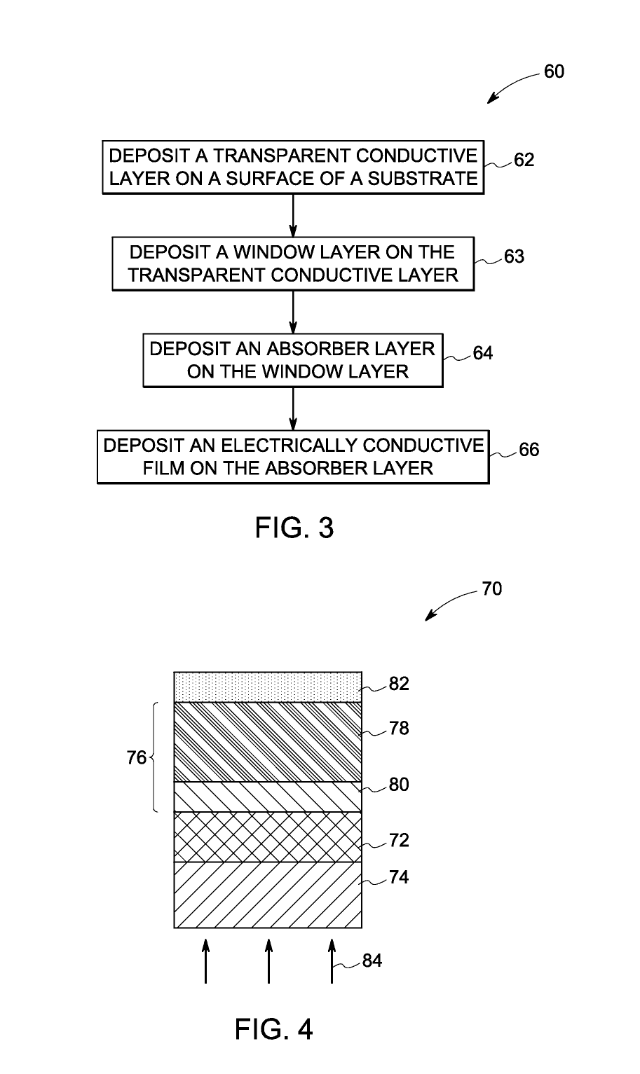

As illustrated in the flow chart 60 of FIG. 3, in certain embodiments, the method of fabricating a thin-film solar cell includes depositing a transparent conductive contact layer on a surface of a substrate (superstrate) (block 62). In one embodiment, the superstrate is made of a transparent material, such as but not limited to, glass; high temperature polyimide; or low temperature, highly transparent polymers, such as PEN, PET and polycarbonate. The transparent conductive contact layer is configured to act as a front electrode for the solar cell. At block 63, a window layer is deposited over the transparent conductive contact layer. At block 64, an absorber layer is deposited on the window layer. The absorber layer and the window layer are oppositely doped and form a semiconductor junction. In one example, the semiconductor junction is formed by depositing an n-type cadmium sulphide window layer on the transparent conductive contact layer, and depositing a p-type cadmium telluride absorber layer on the window layer. In the presently contemplated embodiment, at least one of the absorber layer and the window layer is deposited by employing wherein at least one of the window layer or the absorber layer is deposited by employing high power pulsed magnetron sputtering. At block 66, an electrically conductive film is deposited on the window layer. In one embodiment, a high resistance transparent oxide layer may be deposited on the transparent conductive contact layer prior to depositing the window layer. In one embodiment, the high resistance transparent oxide layer may be deposited by employing high power pulsed magnetron sputtering. The high resistance transparent oxide layer may include zinc oxide (ZnO), tin oxide (SnOₓ), zinc tin oxide (Zn₂SnO₄), zinc magnesium oxide (ZnMgO₂), titanium dioxide (TiO₂), zirconium dioxide (ZrO₂), or other transition metal oxides.

Turning now to FIG. 4, a side view of a solar cell 70 fabricated using the method of FIG. 4 is illustrated. The solar cell 70 includes a transparent conductive contact layer 72 disposed on a surface of the substrate 74. The substrate 74 is made of a transparent material, such as glass or polyimide film. In the illustrated embodiment, where the substrate 74 is transparent, light passes through the substrate 74 and the transparent conductive contact layer 72 and enters the semiconductor junction 76 that is disposed on the transparent conductive contact layer 72. In one embodiment, doped high-conductivity tin oxide, or indium tin oxide may be employed in the transparent conductive contact layer 72. The junction 76 includes an absorber layer 78 and a window layer 80. It is desirable to have a lower thickness of the window layer 80 to prevent light from being absorbed in the window layer 80. An electrically conductive layer 82 is disposed on the semiconductor junction 76. In the illustrated embodiment, the electrically conductive layer 82 is configured to act as a back electrode layer for the solar cell 70. Arrows 84 represents the direction from which the light enters the solar cell 70.

In one embodiment, the window layer 80 is made of n-type cadmium sulphide, and the absorber layer 78 is made of p-type cadmium telluride. The transparent conductive contact layer 72 is made of doped high-conductivity tin oxide or cadmium tin oxide (Cd₂SnO₄). The substrate 74 may include a glass or polyimide layer. The electrically conductive layer 82 may include ZnTe:Cu. Although not illustrated, in one embodiment a high resistance transparent oxide layer may be present between the transparent conductive contact layer 72 and the window layer 80.

FIG. 5 illustrates a schematic representation of a modular arrangement 110 for making the solar cells of the present technique by employing roll-to-roll processing. In the illustrated embodiment, the high power pulsed magnetron sputtering system includes a plurality of modules including a module 112 for depositing ohmic contact, a module 114 for depositing absorber layer, a module 116 for depositing window layer, and a module 118 for depositing transparent conductive contact layer. It should be noted that the arrangement 110 may have fewer or more number of modules than illustrated in FIG. 5. The number of modules may depend on the total number of layers employed in a solar cell. For example, a solar cell employing a p-i-n junction may require an additional module (for deposition of the intrinsic layer) as compared to a solar cell employing a p-n junction. As illustrated by arrows 120 and 122, in one embodiment, the fabrication of the solar cell may either start from module 112 and end at module 118 to fabricate a solar cell structure similar to that illustrated in FIG. 2. Alternatively, the fabrication of the solar cell may start from module 118 and end at the module 112 to fabricate a solar cell structure similar to that illustrated in FIG. 4. The rolls 124 and 126 are made of substrate and superstrate materials, respectively. As will be appreciated, the different layers of the solar cell may require different process conditions, such as temperature, pressure, or flux density, for deposition of the layers. Accordingly, in one embodiment, an operation condition in at least one of the plurality of modules is different than an operation condition in the remaining modules. Further, each of the modules 112, 114, 116 and 118 may have one or more targets for high power pulsed magnetron sputtering systems. For example, in one embodiment, the modules 112, 116 and 118 employ single targets 128, 130 and 132, respectively, whereas the module 114 that is configured to deposit absorber layer may include two sputtering targets 134 and 136. In this embodiment where the module 114 employs two targets, the absorber layer may include CIGS layer that may be formed by co-sputtering from two targets, such as a copper-indium-gallium alloy target and a selenium target. Alternatively, co-sputtering may include sputtering from a copper selenium (Cu₂Se) target and an indium gallium selenium ((In,Ga)₂Se₃) target.

In one example, a portion of a 124 formed of the material employed in substrate, such as polyimide, is first processed in the module 112 to deposit an electrically conductive layer on the substrate using high power pulsed magnetron sputtering. The portion of the substrate having the electrically conductive layer is then subjected to module 114, where absorber layer material, such as CIGS, is deposited on the electrically conductive layer using the high power pulsed magnetron sputtering. In one example, the CIGS absorber layer is deposited by employing co-sputtering. In another example, a CIGS target is employed in high power pulsed magnetron sputtering to deposit CIGS layer on the electrically conductive layer. Alternatively, the physical conditions of the module may be altered to facilitate deposition of the CIGS layer. For example, while depositing CIGS layer, a CIG alloy target may be used in combination with hydrogen selenide (H₂Se) or selenium vapor in the process chamber of the module 114 to deposit CIGS layer. Next, at module 116, a window layer material, such as cadmium sulphide or zinc sulphide, is deposited on the absorber layer to form a semiconductor junction using the high power pulsed magnetron sputtering. Subsequently, in module 118, a transparent conductive contact layer material, such as doped high-conductivity ZnO, is deposited on the semiconductor junction using the high power pulsed magnetron sputtering. In these sputtering modules for manufacturing a certain capacity of solar cells, the optimal process parameters are dependent on the materials being deposited. A good range in general is: pressure 5-20 mTorr, substrate temperature about 0.2-0.5 Tₘ of the material being deposited, high power density about 300-500 W/cm², and pulse length about 0.5-1.5 milliseconds. The average power to each target is depending on the deposition rate desired to meet the throughput requirement, and thus the plasma pulsing frequency varies to meet the average power needs.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of fabricating a thin-film solar cell, comprising:
depositing a transparent conductive contact layer on a surface of a substrate, wherein the transparent conductive contact layer is configured to act as a front electrode for the solar cell;
depositing a window layer over the transparent conductive contact layer;
depositing an absorber layer on the window layer, wherein the absorber layer and the window layer are oppositely doped and form a semiconductor junction, and wherein at least one of the window layer and the absorber layer is deposited by employing high power pulsed magnetron sputtering; and
depositing an electrically conductive film on the semiconductor junction, wherein the electrically conductive film is configured to act as a back electrode layer for the solar cell.

2. The method of claim 1, further comprising depositing a high resistance transparent oxide layer on the transparent conductive contact layer prior to depositing the window layer.

3. The method of claim 2, where the high resistance transparent oxide layer is deposited by employing high power pulsed magnetron sputtering.

4. The method of claim 2, wherein the high resistance transparent oxide layer comprises zinc oxide (ZnO), tin oxide (SnOₓ), zinc tin oxide (Zn₂SnO₄), zinc magnesium oxide (ZnMgO₂), titanium dioxide (TiO₂), zirconium dioxide (ZrO₂), or other transition metal oxides.

5. The method of claim 1, wherein the high power pulsed magnetron sputtering comprises a power density in a range of about 0.1 kW/cm² to about 1 kW/cm², and a current density in a range of about 0.2 A/cm² to about 2 A/cm².

6. The method of claim 1, wherein the high power pulsed magnetron sputtering comprises a pulse length in a range of about 0.2 milliseconds to about 3 milliseconds.

7. The method of claim 1, wherein the modulated pulse plasma is in a frequency range of about 1 Hz to about 1000 Hz.

8. The method of claim 1, wherein the ratio of ionic species to neutral species in plasma is greater than about 30 percent.

9. The method of claim 1, wherein the absorber layer comprises cadmium telluride (CdTe), cadmium zinc telluride (CdZnTe), cadmium magnesium telluride (CdMgTe), mercury cadmium telluride (HgCdTe), or other CdTe-based systems; copper indium disulfide (CIS), copper indium diselenide (CIS), copper indium gallium diselenide (CIGS), copper indium gallium sulfur selenium (CIGSS), copper indium gallium aluminum sulfur selenium (Cu(In,Ga,Al)(S,Se)₂), copper zinc tin sulfide (CZTS) and other CIS-based systems; amorphous silicon, hydrogenated amorphous silicon, microcrystalline silicon, nanocrystalline silicon, or other silicon-based systems; or combinations thereof.

10. The method of claim 1, wherein the method does not comprise a post-deposition step.

11. The method of claim 1, wherein the transparent conductive contact layer comprises cadmium tin oxide (Cd₂SnO₄).

12. A method of fabricating a thin-film solar cell, comprising:
depositing a transparent conductive contact layer on a surface of a substrate;
depositing an n-type window layer on the transparent conductive contact layer;
depositing a p-type cadmium telluride absorber layer on the window layer; and
depositing an electrically conductive film as a back electrode layer,
wherein at least one of the layers is deposited by employing high power pulsed magnetron sputtering.

13. A method of fabricating a solar cell, comprising:
depositing an electrically conductive layer on a surface of a substrate;
depositing an absorber layer on the electrically conductive layer;
depositing a window layer on the absorber layer, wherein the absorber layer and the window layer are oppositely doped and form a semiconductor junction, and wherein high power pulsed magnetron sputtering is employed to deposit at least one of the absorber layer and the window layer; and
depositing a transparent conductive contact layer on the window layer.

14. The method of claim 13, further comprising depositing a high resistance transparent oxide layer on the window layer prior to depositing the transparent conductive contact layer.

15. The method of claim 14, where the high resistance transparent oxide layer is deposited by employing high power pulsed magnetron sputtering.

16. The method of claim 14, wherein the high resistance transparent oxide layer comprises zinc oxide (ZnO), tin oxide (SnOₓ), or zinc tin oxide (Zn₂SnO₄), zinc magnesium oxide (ZnMgO₂), titanium dioxide (TiO₂), zirconium dioxide (ZrO₂), or other transition metal oxides.

17. The method of claim 13, wherein the high power pulsed magnetron sputtering comprises a power density in a range of about 0.1 kW/cm² to about 1 kW/cm², and a current density in a range of about 0.2 A/cm² to about 2 A/cm^{2’}.

18. The method of claim 13, wherein the high power pulsed magnetron sputtering comprises a pulse length in a range of about 0.2 milliseconds to about 3 milliseconds.

19. The method of claim 13, wherein the modulated pulse plasma is in a frequency range of about 1 Hz to about 1000 Hz.

20. The method of claim 13, wherein the ratio of ionic species to neutral species in plasma is greater than about 30 percent.

21. The method of claim 13, wherein the substrate temperature (in K) during the depositing of the junction, electrically conductive layer, transparent conductive contact layer and high resistance transparent oxide layer is lower than 0.3 times of the melting point (Tₘ, in K) of a material being deposited.

22. The method of claim 13, wherein the absorber layer comprises copper indium disulfide (CIS), copper indium diselenide (CIS), copper indium gallium diselenide (CIGS), copper indium gallium sulfur selenium (CIGSS), copper indium gallium aluminum sulfur selenium (Cu(In,Ga,Al)(S,Se)₂), copper zinc tin sulfide (CZTS) and other CIS-based systems; amorphous silicon, hydrogenated amorphous silicon, microcrystalline silicon, nanocrystalline silicon, or other silicon-based systems; cadmium telluride (CdTe), cadmium zinc telluride (CdZnTe), cadmium magnesium telluride (CdMgTe), mercury cadmium telluride (HgCdTe), or other CdTe-based systems; or combinations thereof.

23. The method of claim 13, wherein the method does not comprise a post-deposition step.

24. A method of fabricating a solar cell, comprising:
depositing a conductive layer on a substrate;
depositing a p-type CIGS absorber layer on the conductive layer;
depositing an n-type window layer on the absorber layer; and
depositing a transparent conductive contact layer,
wherein at least one of the layers is deposited by employing high power pulsed magnetron sputtering.
